(19) United States
(12) Patent Application Publication
(10) Pub. No.: US 2024/0105587 A1
(43) Pub. Date: Mar. 28, 2024

(54) SEMICONDUCTOR DEVICE AND METHOD FOR MANUFACTURING THE SAME

(71) Applicant: INNOSCIENCE (SUZHOU) SEMICONDUCTOR CO., LTD., Suzhou City (CN)

(72) Inventors: Hui YAN, Suzhou City (CN); Sichao LI, Suzhou City (CN)

(21) Appl. No.: 17/767,428

(22) PCT Filed: Mar. 2, 2022
(86) PCT No.: PCT/CN2022/078724

§ 371 Date: Apr. 7, 2022

(51) Int. Cl. H01L 23/522; H01L 23/528; H01L 29/20; H01L 29/66; H01L 29/778

(52) U.S. Cl. CPC H01L 23/5226; H01L 23/5283; H01L 29/2003; H01L 29/66462; H01L 29/7786

(57) ABSTRACT

The semiconductor device includes a substrate, a first and a second nitride-based semiconductor multiple layered structures, a first and a second conductive layers. The substrate has a device region and a peripheral region that encloses the device region. The first nitride-based semiconductor multiple layered structure covers the device region and has an edge in the peripheral region. The second nitride-based semiconductor multiple layered structure is within the peripheral region. The first nitride-based semiconductor multiple layered structure is separated from the second nitride-based semiconductor multiple layered structure. The first conductive layer extends from the device region to the peripheral region. The first conductive layer includes a first portion filling into a region between the first and second nitride-based semiconductor multiple layered structures. The second conductive layer is disposed between the second nitride-based semiconductor multiple layered structure and the first conductive layer and electrically coupled to the first conductive layer.

### FIELD OF THE INVENTION

The present invention generally relates to a nitride-based semiconductor device. More specifically, the present invention relates to a nitride-based semiconductor device with a through-GaN via (TGV) structure.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY OF THE INVENTION

In accordance with one aspect of the present disclosure, a semiconductor device is provided. The semiconductor device includes a substrate, a first nitride-based semiconductor multiple layered structure, a second nitride-based semiconductor multiple layered structure, a first conductive layer, and a second conductive layer. The substrate has a device region and a peripheral region that encloses the device region. The first nitride-based semiconductor multiple layered structure is disposed over the substrate. The first nitride-based semiconductor multiple layered structure covers the device region and has an edge in the peripheral region. The second nitride-based semiconductor multiple layered structure is disposed over the substrate and within the peripheral region. The first nitride-based semiconductor multiple layered structure is separated from the second nitride-based semiconductor multiple layered structure. The first conductive layer is disposed over the first nitride-based semiconductor multiple layered structure and extends from the device region to the peripheral region. The first conductive layer includes a first portion filling into a region between the first and second nitride-based semiconductor multiple layered structures. The second conductive layer is disposed between the second nitride-based semiconductor multiple layered structure and the first conductive layer and electrically coupled to the first conductive layer.

In accordance with one aspect of the present disclosure, method for manufacturing a semiconductor device is provided. The method includes steps as follows. A nitride-based semiconductor multiple layered structure is formed over a substrate. A nitride-based transistor and a conductive structure are formed over the nitride-based semiconductor multiple layered structure. The nitride-based transistor is located within a device region of the substrate and the conductive structure is located within a peripheral region of the substrate. A first portion of the nitride-based semiconductor multiple layered structure is removed to expose a first portion of the substrate. A conductive layer is formed to extend from the device region to the peripheral region, so as to cover the first portion of the substrate and the conductive structure.

In accordance with one aspect of the present disclosure, a semiconductor device is provided. The semiconductor device includes a substrate, a nitride-based semiconductor multiple layered structure, a first through-GaN via (TGV) structure, and a conductive structure. The substrate has a device region and a peripheral region that encloses the device region. The nitride-based semiconductor multiple layered structure is disposed over the substrate and covering the device region and the peripheral region. The first through-GaN via (TGV) structure penetrates the nitride-based semiconductor multiple layered structure to make contact with the substrate at the peripheral region. The conductive structure is disposed over the nitride-based semiconductor multiple layered structure and located within the peripheral region of the substrate and out of the device region. The first TGV structure is located between the device region and the conductive structure.

Based on the above, in embodiments of the present disclosure, a portion of the first conductive layer located between the two nitride-based semiconductor multiple layered structures fills a region therebetween, and such a configuration can prevent the cracks, which might be generated during the dicing process. Moreover, a part of the first conductive layer is disposed in the device region, and a second conductive layer located in the peripheral region is electrically connected to the first conductive layer. Hence, the first and second conductive layers can conduct the static electricity generated during the dicing process to the ground. Therefore, the semiconductor device can have good reliability and good electrical properties.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1 is a top view of a wafer according to some embodiments of the present disclosure;

FIG. 2A is a top view of a semiconductor device according to some embodiments of the present disclosure;

FIG. 2B is a vertical cross-sectional view of the semiconductor device along the line I-I′ in the FIG. 2A;

FIG. 3A, FIG. 3B, FIG. 3C, and FIG. 3D show different stages of a method for manufacturing a nitride-based semiconductor device according to some embodiments of the present disclosure;

FIG. 4 is a vertical cross-sectional view of a semiconductor device according to some embodiments of the present disclosure;

FIG. 5 is a vertical cross-sectional view of a semiconductor device according to some embodiments of the present disclosure; and

FIG. 6 is a vertical cross-sectional view of a semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “above,” “on,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

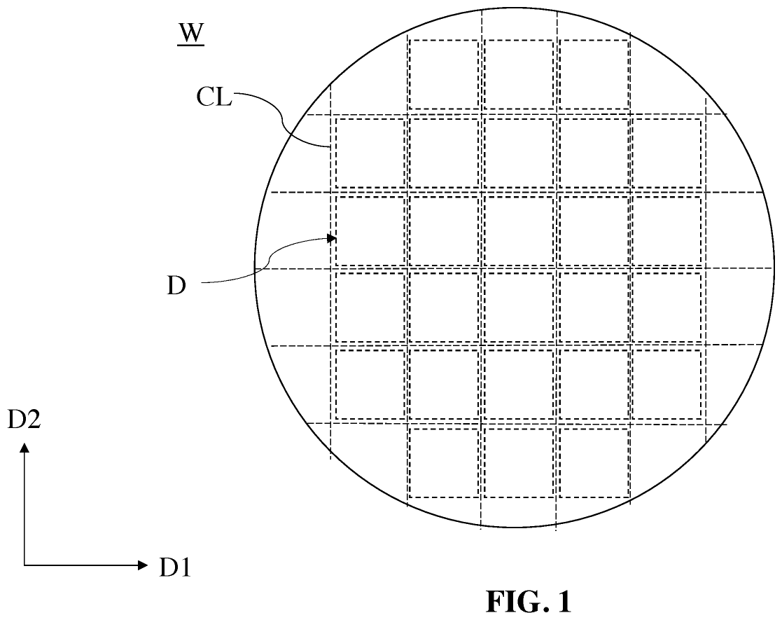

FIG. 1 is a top view of a wafer W according to some embodiments of the present disclosure. A wafer W is formed with a plurality of the semiconductor devices 1A. The semiconductor devices 1A can be formed in an array thereon. In some embodiments, a dicing process/singulation process is performed on the wafer W along the cut lines, such that a plurality of the semiconductor devices can be divided from the wafer W. Each of dashed region D can serve as a semiconductor device.

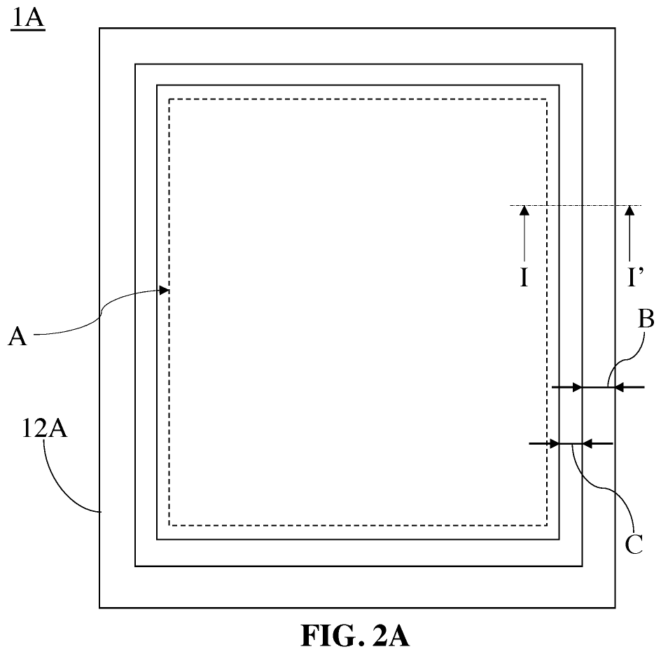

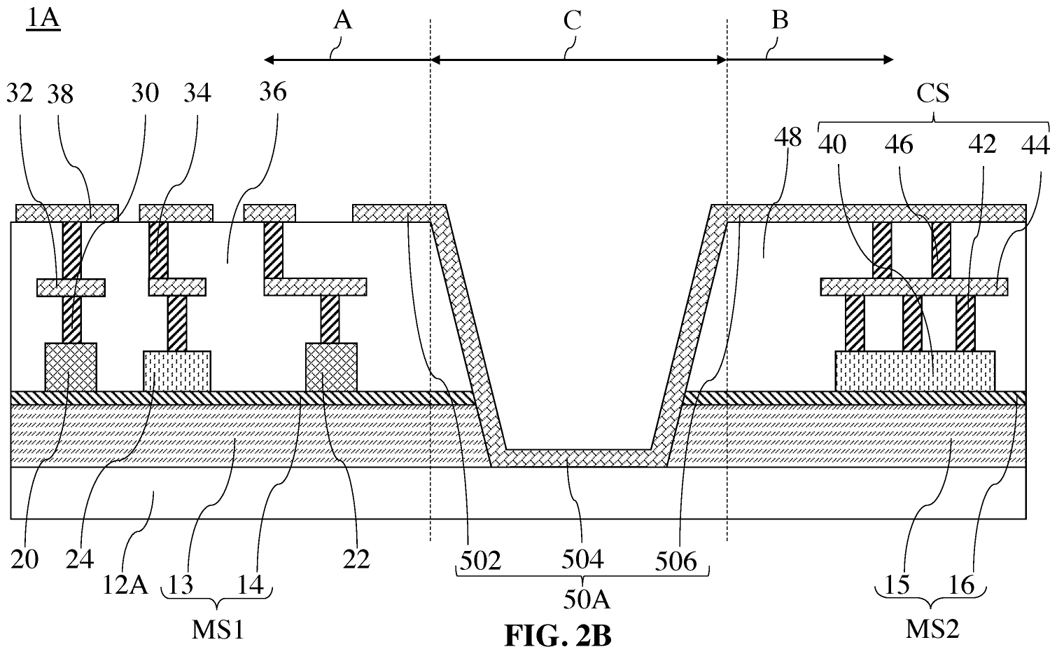

FIG. 2A is a top view of a semiconductor device 1A according to some embodiments of the present disclosure. FIG. 2B is a vertical cross-sectional view of the semiconductor device 1A along the line I-I′ in the FIG. 2A.

The semiconductor device 1A includes a substrate 12A, nitride-based semiconductor multiple layered structures MS1, MS2, electrodes 20, 22, a gate electrode 24, a plurality of contact vias 30, a conductive layer 32, a plurality of contact vias/conductive vias 34, a dielectric structure 36, a patterned circuit layer 38, a conductive layer 40, a plurality of contact vias 42, a conductive layer 44, a plurality of contact vias 46, and a conductive layer 50A.

The substrate 12A may be a semiconductor substrate. The exemplary materials of the substrate 12A can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 12A can include, for example, but is not limited to, group III elements, group IV elements, group V elements, or combinations thereof (e.g., III-V compounds). In other embodiments, the substrate 12A can include, for example but is not limited to, one or more other features, such as a doped region, a buried layer, an epitaxial (epi) layer, or combinations thereof.

During the dicing process, a diamond tipped scribe can be moved across the wafer surface along to form scribe lines. These scribe lines extend along the spaces between the devices. These spaces are commonly referred to as “streets.” The diamond scribe forms shallow scratches in the wafer surface along the streets. Then, upon the application of pressure, such as with a roller, the wafer separates along the scribe lines. The cracks can be formed and propagate from an edge of the device into the inside thereof. The cracks in the wafer may follow a crystal lattice structure, such as epitaxial growth structures. Furthermore, the electrostatic damage caused by the dicing process is hard to prevent. Thus, the quality/reliability and yield of the device would be worsened.

At least to avoid the afore-mentioned issues, the present disclosure is to provide a novel structure/configuration for the nitride-based semiconductor devices.

Referring to the FIGS. 2A and 2B, in embodiments of the present disclosure, it should be noted that the substrate 12A can have a device region A (i.e., active region), regions B and C. The region B in combination with the region C can be viewed as a peripheral region of the substrate 12A. The peripheral region encloses/surrounds the device region A. The region C is located between the device region A and the region B. The device region A is separated from the region B by the region C. The peripheral region defines a boundary of the semiconductor device 1A.

The configuration of the aforesaid elements in the semiconductor 1A in the three regions A, B and C will be fully described as follows.

With respect to the device region A, at least a portion of the nitride-based semiconductor multiple layered structure MS1 covers the device region A. The nitride-based semiconductor multiple layered structure MS1 is disposed on/over/above the substrate 12A. The nitride-based semiconductor multiple layered structure MS1 includes nitride-based semiconductor layers 13, 14.

The nitride-based semiconductor layer 13 is disposed on/over/above the substrate 12A. The nitride-based semiconductor layer 14 is disposed on/over/above the nitride-based semiconductor layer 13. At least a portion of the nitride-based semiconductor layer 13 and at least a portion of the nitride-based semiconductor layer 14 are located in the device region A. The exemplary materials of the nitride-based semiconductor layer 13 can include, for example but are not limited to, nitrides or group III-V compounds, such as GaN, AlN, InN, InₓAl_{y}Ga_{(1-x-y)}N where x+y≤1, AlₓGa₍₁₋ₓ₎N where x≤1. The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 13 and 14 are selected such that the nitride-based semiconductor layer 14 has a bandgap (i.e., forbidden band width) greater than a bandgap of the nitride-based semiconductor layer 13, which causes electron affinities thereof different from each other and forms a heterojunction therebetween. For example, when the nitride-based semiconductor layer 13 is an undoped GaN layer having a bandgap of approximately 3.4 eV, the nitride-based semiconductor layer 14 can be selected as an AlGaN layer having bandgap of approximately 4.0 eV. As such, the nitride-based semiconductor layers 13 and 14 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT) in the device region A, and the aforesaid nitride-based transistor is disposed on/over/above the nitride-based semiconductor multiple layered structure MS1 and located within the device region A.

In other embodiments, the other kinds of nitride-based active components (e.g., the integrated circuit package, transistors, diodes, power sources, or displays) can be formed in the device region A, and the present disclosure is not limited thereto.

The electrodes 20, 22 and the gate electrode 24 are located/disposed in the device region A. The electrodes 20, 22 and the gate electrode 24 are disposed on/over/above the nitride-based semiconductor layer 14. The electrodes 20, 22 and the gate electrode 24 are located/disposed in the device region A. The electrodes 20, 22 and the gate electrode 14 can constitute a HEMT device with the 2DEG region in the device region A. In the embodiment, the semiconductor device 1A is a depletion-mode device, which means the semiconductor device 1A in a normally-on state at zero gate-source voltage.

The electrodes 20 and 22 are in contact with the nitride-based semiconductor layer 14. In some embodiments, the electrode 20 can serve as a source electrode. In some embodiments, the electrode 20 can serve as a drain electrode. In some embodiments, the electrode 22 can serve as a source electrode. In some embodiments, the electrode 22 can serve as a drain electrode. The role of the electrodes 20 and 22 depends on the device design.

In some embodiments, the electrodes 20 and 22 can include, for example but are not limited to, metals, alloys, doped semiconductor materials (such as doped crystalline silicon), compounds such as silicides and nitrides, other conductor materials, or combinations thereof. The exemplary materials of the electrodes 20 and 22 can include, for example but are not limited to, Ti, AlSi, TiN, or combinations thereof. Each of the electrodes 20 and 22 may be a single layer, or plural layers of the same or different composition. The electrodes 20 and 22 form ohmic contacts with the nitride-based semiconductor layer 14. Furthermore, the ohmic contacts can be achieved by applying Ti, Al, or other suitable materials to the electrodes 20 and 22. In some embodiments, each of the electrodes 20 and 22 is formed by at least one conformal layer and a conductive filling. The conformal layer can wrap the conductive filling. The exemplary materials of the conformal layer can include, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The exemplary materials of the gate electrode 24 may include metals or metal compounds. The gate electrode 24 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

The contact vias 30 are located in the device region A. The contact vias 30 are disposed on/over/above the electrodes 20, 22, and the gate electrode 24, respectively. The contact vias 30 can extend longitudinally to connect to the electrodes 20, 22 and the gate electrode 24, respectively. The exemplary materials of the contact vias 30 can include, for example but are not limited to, conductive materials, such as metals or alloys.

The conductive layer 32 is located in the device region A. The conductive layer 32 is disposed on/over/above the contact vias 30, and make contact with the contact vias 30. The exemplary materials of the conductive layer 32 can include, for example but are not limited to, conductive materials, such as metals or alloys.

The contact vias 34 are located in the device region A. The contact vias 34 are disposed on/over/above the conductive layer 32. The contact vias 34 can extend longitudinally to connect to the conductive layer 32. The exemplary materials of the contact vias 34 can include, for example but are not limited to, conductive materials, such as metals or alloys.

At least a portion of the dielectric structure 36 is located in the device region A. The dielectric structure 36 is disposed between the nitride-based semiconductor multiple layered structure MS1 and the conductive layer 50A. The electrodes 20, 22, the gate electrode 24, the contact vias 30, the conductive layer 32 and the contact vias 34 are disposed (or embedded) in the dielectric structure 36. Top surfaces of the contact vias 34 are free from coverage of the dielectric structure 36. Moreover, the dielectric structure 36 can serve as a planarization layer which has a level top surface to support other layers/elements. In some embodiments, the dielectric structure 36 can be formed as a thicker layer, and a planarization process, such as chemical mechanical polish (CMP) process, is performed on the dielectric structure 36 to remove the excess portions, thereby forming a level top surface.

The material of the dielectric structure 36 can include, for example but are not limited to, dielectric materials. For example, the dielectric layer 120 can include, for example but are not limited to, SiNₓ, SiOₓ, Si₃N₄, SiON, SiC, SiBN, SiCBN, oxides, nitrides, plasma enhanced oxide (PEOX), or combinations thereof. In some embodiments, the dielectric structure 36 can be a multi-layered structure, such as a composite dielectric layer of Al₂O₃/SiN, Al₂O₃/SiO₂, AlN/SiN, AlN/SiO₂, or combinations thereof. In some embodiments, the optional dielectric layer can be formed by a single layer or more layers of dielectric materials. The exemplary dielectric materials can include, for example but are not limited to, one or more oxide layers, a SiOₓ layer, a SiNₓ layer, a high-k dielectric material (e.g., HfO₂, Al₂O₃, TiO₂, HfZrO, Ta₂O₃, HfSiO₄, ZrO₂, ZrSiO₂, etc), or combinations thereof.

The patterned conductive layer 38 is disposed on the dielectric structure 36 and the contact vias 34. The patterned conductive layer 38 is in contact with the contact vias 34. The patterned conductive layer 38 may have metal lines, pads, traces, or combinations thereof, such that the patterned conductive layer 38 can form at least one circuit. The exemplary materials of the patterned conductive layer 38 can include, for example but are not limited to, conductive materials. The patterned conductive layer 38 may include a single film or multilayered film having Ag, Al, Cu, Mo, Ni, Ti, alloys thereof, oxides thereof, nitrides thereof, or combinations thereof.

With respect to the region B of the peripheral region, the nitride-based semiconductor multiple layered structure MS2 is within the region B of the peripheral region. The nitride-based semiconductor multiple layered structure MS2 is disposed on/over/above the substrate 12A. The nitride-based semiconductor multiple layered structure MS2 includes nitride-based semiconductor layers 15, 16. The configuration and the exemplary materials of the nitride-based semiconductor layers 15, 16 can be similar or identical with the nitride-based semiconductor layers 13, 14, respectively.

The conductive layer 40 is located in the region B of the peripheral region. The conductive layer 40 is disposed on/over/above the nitride-based semiconductor layer 16. The exemplary materials of the conductive layer 40 can be similar or identical with the gate electrode 24.

The contact vias 42 are located in the region B of the peripheral region. The contact vias 42 are disposed on/over/above the conductive layer 40. The contact vias 42 can extend longitudinally to connect to the conductive layer 40. The exemplary materials of the contact vias 42 can include, for example but are not limited to, conductive materials, such as metals or alloys.

The conductive layer 44 is located in the region B of the peripheral region. The conductive layer 44 is disposed on/over/above the contact vias 42. The conductive layer 44 is in contact with the contact vias 42. The contact vias 42 are disposed between the conductive layer 44 and the conductive layer 40. The conductive layer 44 is electrically coupled to the conductive layer 50A through the contact vias 46. The exemplary materials of the conductive layer 44 can include, for example but are not limited to, conductive materials, such as metals or alloys.

The contact vias 46 are located in the region B of the peripheral region. The contact vias 46 are disposed on/over/above the conductive layer 44. The contact vias 46 can extend longitudinally to connect to the conductive layer 44. The conductive layer 44 is electrically coupled to the conductive layer 50A through the contact vias 46. The exemplary materials of the contact vias 46 can include, for example but are not limited to, conductive materials, such as metals or alloys.

The contact vias 46, the conductive layer 44, the contact vias 42, and the conductive layer 40 can constitute a conductive structure CS. The conductive structure CS is disposed on/over/above the nitride-based semiconductor multiple layered structure MS2. The conductive structure CS is located within the region B of the peripheral region of the substrate 12A and out of the device region A.

At least a portion of the dielectric structure 48 is located in the region B of the peripheral region. The dielectric structure 48 is disposed between the nitride-based semiconductor multiple layered structure MS2 and the conductive layer 50A. The conductive layer 40, the contact vias 42, the conductive layer 44, the contact vias 44, and the contact vias 46 are disposed (or embedded) in the dielectric structure 48. Top surfaces of the contact vias 46 are free from coverage of the dielectric structure 48. The thickness of the dielectric structure 48 can be the same as that of the dielectric structure 36. Moreover, the dielectric structure 48 can serve as a planarization layer which has a level top surface to support other layers/elements. In some embodiments, the dielectric structure 48 can be formed as a thicker layer, and a planarization process, such as CMP process, is performed on the dielectric structure 48 to remove the excess portions, thereby forming a level top surface. The dielectric structure 48 can block moisture entering into the device. In some embodiments, the dielectric structure 48 can serve as a sealing structure and function as a moisture blocking structure.

With respect to the region C of the peripheral region, each of the nitride-based semiconductor multiple layered structure MS1 and MS2 has an edge in the region C of the peripheral region. Each of the nitride-based semiconductor layers 13, 14 of the nitride-based semiconductor multiple layered structure MS1 and the dielectric structure 36 has an oblique sidewall, and the slopes of these sidewalls are the same, thereby forming a continuous and oblique sidewall. On the other hand, each of the nitride-based semiconductor layers 15, 16 of the nitride-based semiconductor multiple layered structure MS2 and the dielectric structure 36 has an oblique sidewall, and the slopes of these sidewalls are the same, thereby forming a continuous and oblique sidewall. The oblique sidewall of the dielectric structure 36 is opposite to the oblique sidewall of the dielectric structure 48. The oblique sidewall of the nitride-based semiconductor multiple layered structure MS1 is opposite to the oblique sidewall of the nitride-based semiconductor multiple layered structure MS2.

The conductive layer 50A extends from the device region A to the region B of the peripheral region through the region C of the peripheral region. The conductive layer 50A extends from a top surface of the dielectric structure 36 to the substrate 12A, in which the conductive layer 50A extends along oblique sidewalls of the dielectric structure 36 and the nitride-based semiconductor multiple layered structure MS1. The conductive layer 50A extends from the substrate 12A to a top surface of the dielectric structure 48, in which the conductive layer 50A extends along oblique sidewalls of the dielectric structure 48 and the nitride-based semiconductor multiple layered structure MS2.

Specifically, the conductive layer 50A includes portions 502, 504 and 506, in which the portion 504 is between and connected to the portions 502 and 506. The portion 502 of the conductive layer 50A is disposed on/over/above on the top surface of the dielectric structure 36. The portion 506 of the conductive layer 50A is disposed on/over/above the top surface of the dielectric structure 48.

The portion 504 of the conductive layer 50A fills into the region C of the peripheral region between the nitride-based semiconductor multiple layered structures MS1 and MS2. The portion 504 viewed along a direction normal to the substrate 12A is in a closed ring shape (see FIG. 2A). The portion 504 further includes two oblique portions and a horizontal portion therebetween. One of the oblique portions of the portion 504 is disposed on/over/above and conformal with the sidewalls of the dielectric structure 36 and the nitride-based semiconductor multiple layered structure MS1. Another one of the oblique portions of the portion 504 is disposed on/over/above and conformal with the sidewalls of the dielectric structure 48 and the nitride-based semiconductor multiple layered structure MS2. The horizontal portion of the portion 504 is in contact with the substrate 12A.

The portion 504 of the conductive layer 50A entirely fills into the region C between the nitride-based semiconductor multiple layered structures MS1 and MS2, such that the nitride-based semiconductor multiple layered structure MS1 is separated from the nitride-based semiconductor multiple layered structure MS2.

The two nitride-based semiconductor multiple layered structures MS1 and MS2 can be considered as a whole nitride-based semiconductor multiple layered structure. The portion 504 of the conductive layer 50A penetrates through the whole nitride-based semiconductor multiple layered structure. In some embodiments, the nitride-based semiconductor layers of the whole nitride-based semiconductor multiple layered structure are stacked GaN-based semiconductor layers. The portion 504 of the conductive layer 50A can serve as a through-GaN via (TGV) structure, as it penetrates through the stacked GaN-based semiconductor layers. The TGV structure penetrates the whole nitride-based semiconductor multiple layered structure to make contact with the substrate 12A at the peripheral region. Furthermore, since the portion 504 can act as the TGV structure, the conductive layer 50A can electrically couple the conductive structure CS to at least one element within the device region A.

With the above configuration, potential cracks can be avoided. For example, during a dicing process, cracks may be created at an edge of a semiconductor device. The cracks are highly created in an epitaxial growth layer, and then the cracks may propagate from an edge to a center region of the epitaxial growth layer, which may affect working component to fail.

In the present disclosure, the whole nitride-based semiconductor multiple layered structure is divided into the separated two nitride-based semiconductor multiple layered structures MS1 and MS2. Therefore, even though cracks are created in the nitride-based semiconductor multiple layered structure MS2 which is adjacent to an edge of the device, the cracks would not enter the nitride-based semiconductor multiple layered structure MS1. It can improve the working reliability of the semiconductor device 1A since the device region A is confined in the nitride-based semiconductor multiple layered structure MS1 and the device region A can be kept free from the cracks. The quality of the active component in the device region A can be assured.

The elements in the device region A and the elements in the region B can be manufactured in the same manufacturing stage. To be more specific, the nitride-based semiconductor multiple layered structures MS1 and MS2 can be simultaneously formed in the same manufacturing stage. Similarly, the conductive layers 44 and 32 are formed in the same layer, such that the conductive layers 44 and 32 can be simultaneously formed in the same manufacturing stage. Also, the gate electrode 24 and the conductive layer 40 can be simultaneously formed in the same manufacturing stage. Due to such a configuration, the manufacturing process of the semiconductor device 1A can be simplified.

In other embodiments, the elements in the device region A and the elements in the region B can be manufactured independently. For example, the two nitride-based semiconductor multiple layered structures MS1 and MS2 can be formed in different manufacturing stages.

In some embodiments, the conductive layer 40 or the conductive layer 44 of the conductive structure CS can be electrically coupled to the ground. That is to say, the conductive structure CS can function as a ground structure. During the dicing process, static electricity may be generated at the edge which is adjacent to the region B of the peripheral region, and such the accumulated static electricity can be discharged to the ground through the conductive structure CS.

In some embodiments, the semiconductor device 1A can further include a ground layer within the device region A and electrically connected to the portion 502 of the conductive layer 50A, so components within the device region A can be conducted to the ground through the conductive layer 50A and the conductive structure CS. Similarly, at an operation stage, static electricity may be generated in the device region A, and such the accumulated static electricity can be conduct can be discharged to the ground through the conductive layer 50A and the conductive structure CS.

The configuration of the conductive layer 50A and the conductive structure CS can collaboratively form at least one electrostatic protection circuit for achieving an electrostatic discharging function. Therefore, the electrostatic discharging capability of the semiconductor device 1A can be greatly enhanced, and the negative impacts of the static electricity can be reduced.

In some embodiments, the conductive structure CS is formed as a double-layer structure. In some embodiments, the conductive structure CS is formed in a closed ring shape to enclose the device region A (see FIG. 2A). In some embodiments, the conductive structure CS continuously surrounds the device region A.

In some embodiments, the semiconductor device 1A further includes a buffer layer (not shown). The buffer layer is disposed between the substrate 12A and the nitride-based semiconductor layer 13/15. The buffer layer can be configured to reduce lattice and thermal mismatches between the substrate 12A and the nitride-based semiconductor layer 13/15, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof.

In some embodiments, the semiconductor device 1A may further include a nucleation layer (not shown). The nucleation layer may be formed between the substrate 12A and a buffer layer. The nucleation layer can be configured to provide a transition to accommodate a mismatch/difference between the substrate 12A and a III-nitride layer of the buffer layer. The exemplary material of the nucleation layer can include, for example but is not limited to AlN or any of its alloys.

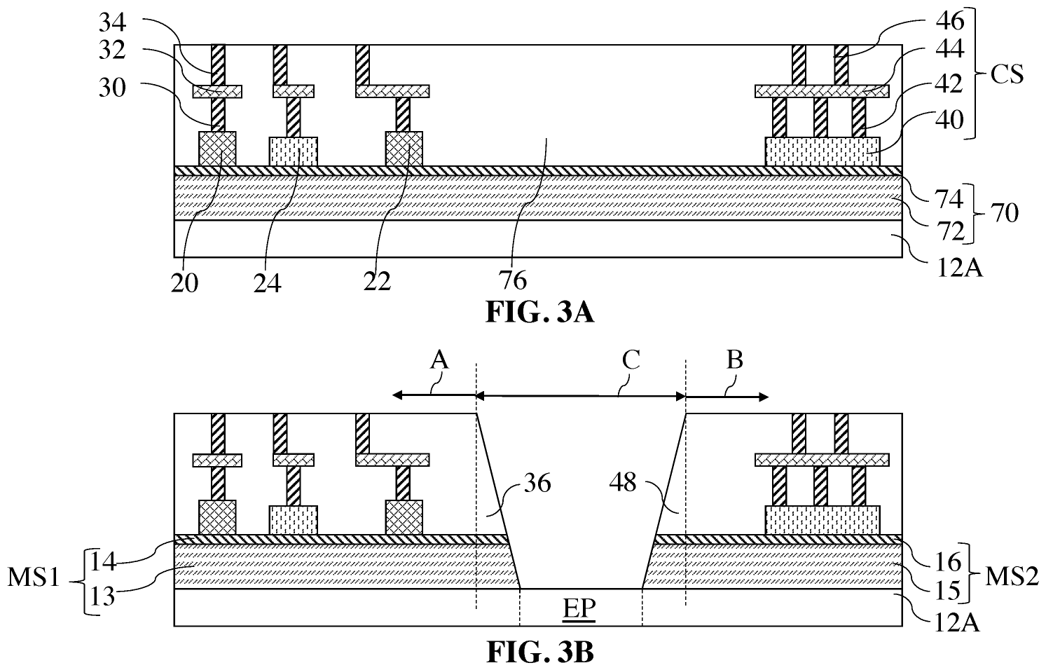

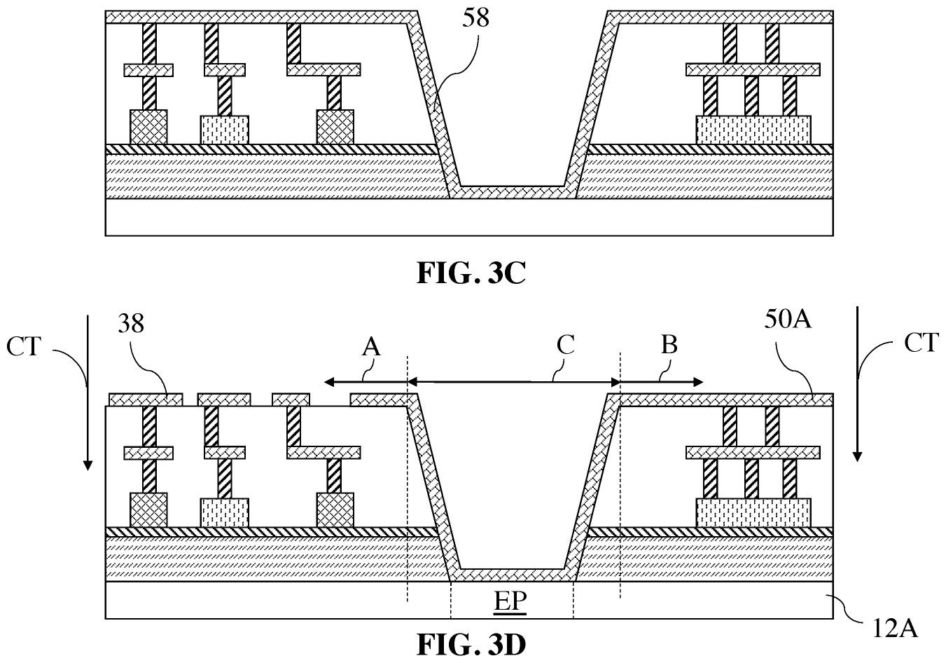

Different stages of a method for manufacturing the semiconductor device 1A are shown in FIG. 3A, FIG. 3B, FIG. 3C, and FIG. 3D, as described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

It should be noted that a plurality of the semiconductor devices 1A can be manufactured/formed on the wafer W in the FIG. 1. The detail manufacturing process of the semiconductor device 1A in one dashed region D in FIG. 1 will be described in detail as follows.

Referring to FIG. 3A, a nitride-based semiconductor multiple layered structure 70 is formed on/over/above a substrate 12A, in which the nitride-based semiconductor multiple layered structure 70 includes nitride-based semiconductor layers 72 and 74. The nitride-based semiconductor layers 72 and 74 can be formed on/over/above the substrate 12A by using the above-mentioned deposition techniques. The nitride-based semiconductor layer 74 is formed on the nitride-based semiconductor layer 72.

At least one nitride-based transistor and a conductive structure CS are formed on/over/above the nitride-based semiconductor multiple layered structure 50. The nitride-based transistor includes electrodes 20, 22 and a gate electrode 24. The contact vias 30, 34, 42, 46, the conductive layers 32 and 44 are formed on/over/above the nitride-based transistor. The conductive structure CS includes conductive layers 40, 44, and a plurality of contact vias 42, 46. An intermediate dielectric structure 76 is formed to cover the nitride-based transistor and the conductive structure CS.

The formation of the each of the electrodes 20, 22, the gate electrode 24, the contact vias 30, 34, 42, 46, the conductive layers 32 and 44 can include deposition techniques and a patterning process. In some embodiments, the patterning process can include photolithography, exposure and development, etching, other suitable processes, or combinations thereof.

Referring to FIG. 3B, a portion of the intermediate dielectric structure 76 and a portion of the nitride-based semiconductor multiple layered structure 70 are removed to expose a portion EP of the substrate 12A, thereby forming the physically separated dielectric structures 36, 48 and the physically separated nitride-based semiconductor multiple layered structures MS1 and MS2. The removing process can include a patterning process.

By employing aforesaid the removing process, each of the dielectric structures 36, 48 and each of the nitride-based semiconductor multiple layered structures MS1 and MS2 can have an oblique sidewall. Moreover, the boundaries of the device region A, the regions B and C of the peripheral region can be well defined. The nitride-based transistor is located within a device region A of the substrate 12A and the conductive structure CS is located within the region B of the peripheral region of the substrate 12A.

Referring to FIG. 3C, an intermediate conductive layer 58 is formed to cover a top surface of the resulted structure of FIG. 3B.

Referring to FIG. 3D, a patterning process is performed on the intermediate conductive layer 58, such that some portions of the intermediate conductive layer 58 are removed, thereby forming the patterned circuit layer 38 and the conductive layer 50A. The conductive layer 50A is formed to extend from the device region A to the peripheral region so as to cover the portion EP of the substrate 12A and the conductive structure CS. A TGV structure of the conductive layer 50A is formed in contact with the portion EP of the substrate 12A.

Next, a dicing/cutting/singulation process is performed. The TGV structure is farther away from at least one of the cut lines than the conductive structure CS. For example, the cut line may be adjacent to the right edge of the structure as shown in FIG. 3D, so the conductive structure CS is located between the TGV structure and the right edge. More specifically, referring to FIG. 1, the wafer W is diced along cut lines CL, such that semiconductor devices can be singulated or be separated individually as shown in the FIG. 3D. In this regard, each of the dashed region D in the FIG. 1 accommodates one semiconductor device. Each the dashed region D is defined by one set of two adjacent cut lines CL extending along a horizontal direction D1 and another set of two adjacent cut lines CL extending along a vertical direction D2. A cutting tool (such as a saw blade, a laser blade, or a diamond tipped scribe) is applied to the dicing process.

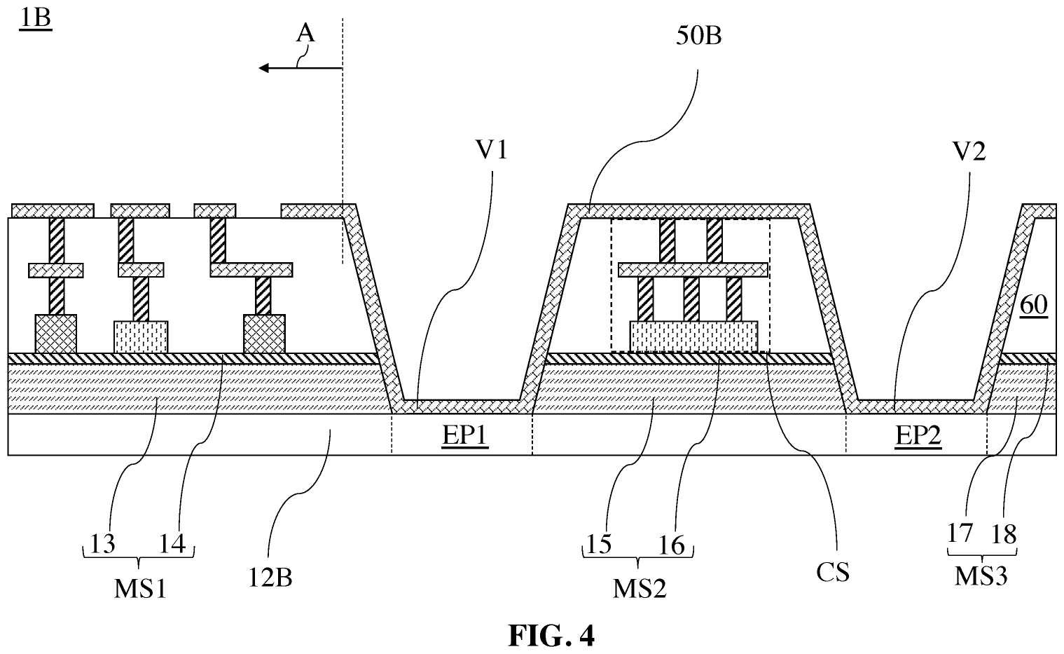

FIG. 4 is a vertical cross-sectional view of a semiconductor device 1B according to some embodiments of the present disclosure. The semiconductor device 1B is similar to the semiconductor device 1A as described and illustrated with reference to FIGS. 2A and 2B, except that the substrate 12A can be replaced by a substrate 12B and that the conductive layer 50A can be replaced by a conductive layer 50B. The semiconductor device 1B further includes a nitride-based semiconductor multiple layered structure MS3 and a dielectric structure 60.

Three physically separated nitride-based semiconductor multiple layered structures MS1, MS2 and MS3 are disposed over the substrate 12B. The nitride-based semiconductor multiple layered structure MS2 is located between the nitride-based semiconductor multiple layered structures MS1 and MS3. A portion EP1 of the substrate 12B is located between the nitride-based semiconductor multiple layered structures MS1, MS2. A portion EP2 of the substrate 12B is located between the nitride-based semiconductor multiple layered structures MS2, MS3.

The nitride-based semiconductor multiple layered structure MS3 further includes nitride-based semiconductor layers 17 and 18. The configuration and the exemplary materials of the nitride-based semiconductor layers 17, 18 can be similar or identical with the nitride-based semiconductor layers 13, 14, respectively. The dielectric structure 60 is disposed on the nitride-based semiconductor layer 18 of the nitride-based semiconductor multiple layered structure MS3.

The conductive layer 50B extends from the device region A across and above the nitride-based semiconductor multiple layered structure MS2. The conductive layer 50B extends across and above the conductive structure CS. The conductive layer 50B further extends to a top surface of the dielectric layer 60. The conductive layer 50B can make contact with the portion EP1 between the nitride-based semiconductor multiple layered structures MS1, MS2. The conductive layer 50B can make contact with the portion EP2 between the nitride-based semiconductor multiple layered structures MS2, MS3. Accordingly, two TGV structures V1 and V2 are formed in the peripheral region. Each of the TGV structures V1 and V2 includes two oblique portions and a horizontal portion therebetween. The TGV structures V1 and V2 penetrate the whole nitride-based semiconductor multiple layered structure to make contact with the portions EP1, EP2 of the substrate 12B at the peripheral region, respectively. A portion of the conductive layer 50B connects the TGV structure V1 near the device region A to the other TGV structure V2.

The dielectric structure 60 is disposed on/over/above the nitride-based semiconductor layer 18 of the nitride-based semiconductor multiple layered structure MS3. The exemplary materials of the dielectric structure 60 can be similar or identical with the dielectric structure 36.

With respect to the semiconductor device 1B, the two TGV structures V1, V2 of the conductive layer 50B can provide a better protection. The nitride-based semiconductor multiple layered structure MS3 can serve as a sacrifice structure. The cracks created in the nitride-based semiconductor multiple layered structure MS3 will stay in the nitride-based semiconductor multiple layered structure MS3 rather than enter the nitride-based semiconductor multiple layered structures MS1 and MS2. Thus, the reliability of the semiconductor device 1B can be further promoted.

During the manufacturing process of the semiconductor device 1B, portions of the nitride-based semiconductor multiple layered structure and portions of the intermediate dielectric structure are removed to expose different portions EP1, EP2 of the substrate 12B, such that the conductive structure CS is located between the portions EP1, EP2 of the substrate 12B. Then, a conductive layer 50B is formed to extend from the device region A to the peripheral region, in which the conductive layer 50B is formed to extend across and above the conductive structure CS to cover the portions EP1, EP2 of the substrate 12B.

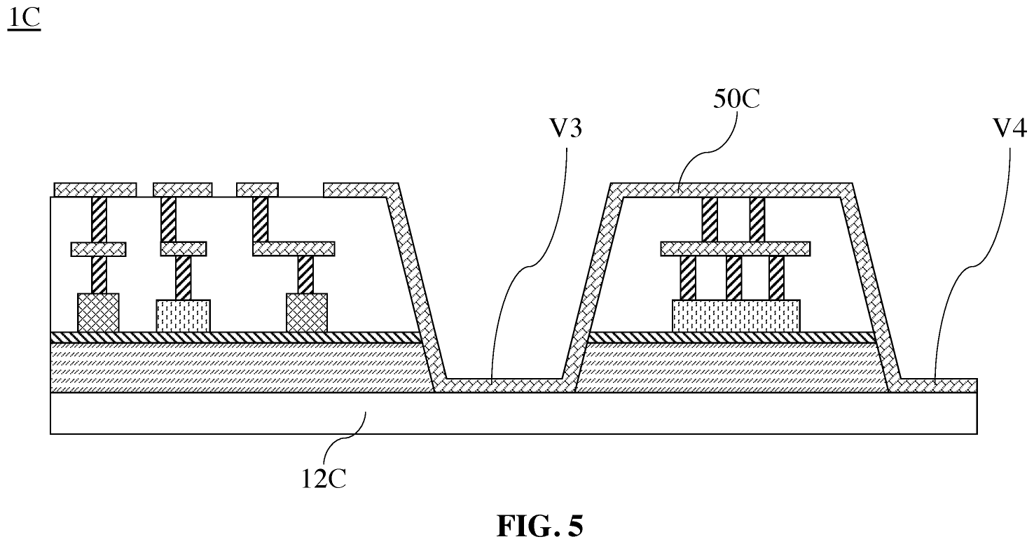

FIG. 5 is a vertical cross-sectional view of a semiconductor device 1C according to some embodiments of the present disclosure. The semiconductor device 1C is similar to the semiconductor device 1B as described and illustrated with reference to FIG. 4, except that the conductive layer 50B can be replaced by the conductive layer 50C. Furthermore, the semiconductor device 1C excludes the nitride-based semiconductor multiple layered structure MS3 and the dielectric layer 60 as shown in FIG. 4.

Specifically, the conducive layer 50C has an end portion away from the device region A. The conducive layer 50C is in direct contact with the substrate 12. In addition, the TGV structure V4 farther away from the device region A than the TGV structure V3 includes an oblique portion and a horizontal portion.

During the manufacturing process of the semiconductor device 1C, the cut line can overlap with the TGV structure V4, the nitride-based semiconductor multiple layered structure MS3, the dielectric layer 60, and a portion of the substrate 12B as shown in FIG. 4 are removed.

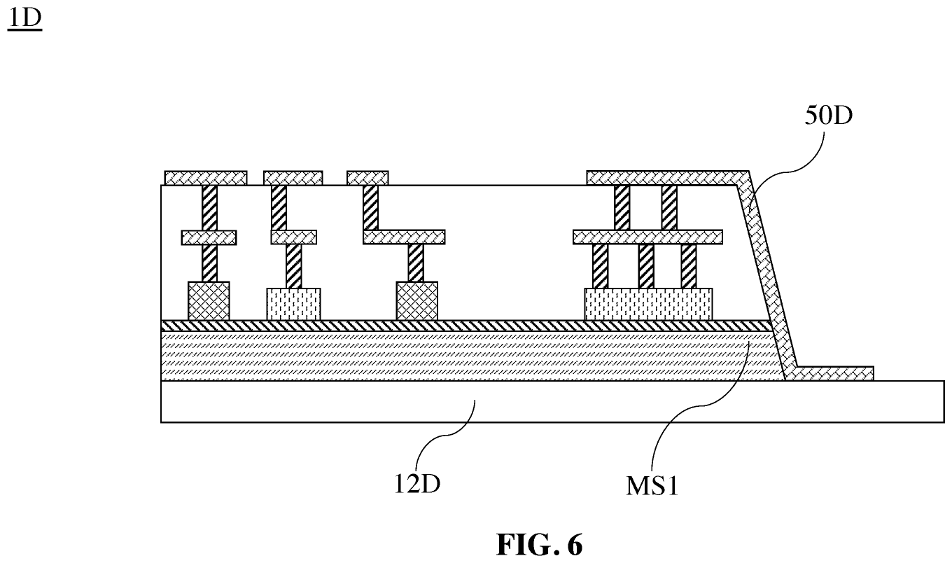

FIG. 6 is a vertical cross-sectional view of a semiconductor device 1D according to some embodiments of the present disclosure. The semiconductor device 1D is similar to the semiconductor device 1C as described and illustrated with reference to FIG. 5, except that the TGV structure V3 is omitted.

The nitride-based semiconductor multiple layered structure MS1 is narrower than the substrate 12D. The nitride-based semiconductor multiple layered structure MS1 is spaced apart from an edge of the substrate 12D. The conductive layer 50D is spaced apart from an edge of the substrate 12D. An end of the substrate 12D adjacent to the edge is free from coverage of the conductive layer 50D. During the dicing process, the cut line can overlap with the end of the substrate 12D so the conductive layer 50D can be kept away from dicing, which avoiding peeling. Moreover, since the nitride-based semiconductor multiple layered structure MS1 is spaced apart from an edge of the substrate 12D, the nitride-based semiconductor multiple layered structure MS1 is free from contact with a dicing tool during the dicing process so it can prevent growth of cracks in the nitride-based semiconductor multiple layered structure MS1.

Based on the above description, in embodiments of the disclosure, the whole nitride-based semiconductor multiple layered structure can be divided into more than one portion so as to avoid propagation of cracks into the device region. TGV technic can be applied to the whole nitride-based semiconductor multiple layered structure. The outer nitride-based semiconductor multiple layered structure can serve as a sacrifice structure, which means the cracks can stay in the sacrifice structure so the device region is free from the cracks. Therefore, the quality of the active component in the device region can be ensured.

Moreover, at least one conductive layer of the conductive structure within in the peripheral region can be electrically coupled to the ground, such that the static electricity generated during the dicing process can conduct to the ground by the conductive structure. Furthermore, the TGV structure is electrically coupled to the conductive layer of the conductive structure within the peripheral region, and thus the accumulated static electricity in the device region can conduct to the ground by the TGV structure. As such, the negative impacts caused by the static electricity can be avoided.

The embodiments were chosen and described in order to best explain the principles of the invention and its practical application, thereby enabling others skilled in the art to understand the invention for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A semiconductor device, comprising:
a substrate having a device region and a peripheral region that encloses the device region;
a first nitride-based semiconductor multiple layered structure disposed over the substrate, wherein the first nitride-based semiconductor multiple layered structure covers the device region and has an edge in the peripheral region;
a second nitride-based semiconductor multiple layered structure disposed over the substrate and within the peripheral region, wherein the first nitride-based semiconductor multiple layered structure is separated from the second nitride-based semiconductor multiple layered structure;
a first conductive layer disposed over the first nitride-based semiconductor multiple layered structure and extending from the device region to the peripheral region, wherein the first conductive layer comprises a first portion filling into a region between the first and second nitride-based semiconductor multiple layered structures; and
a second conductive layer disposed between the second nitride-based semiconductor multiple layered structure and the first conductive layer and electrically coupled to the first conductive layer.

2. The semiconductor device of claim 1, wherein the first portion of the first conductive layer is in contact with the substrate.

3. The semiconductor device of claim 2, wherein the first portion of the first conductive layer viewed along a direction normal to the substrate is in a closed ring shape.

4. The semiconductor device of claim 1, further comprising:
a first dielectric structure disposed between the first nitride-based semiconductor multiple layered structure and the first conductive layer, wherein the first conductive layer extends from a top surface of the first dielectric structure to the substrate.

5. The semiconductor device of claim 4, wherein the first conductive layer extends along oblique sidewalls of the first dielectric structure and the first nitride-based semiconductor multiple layered structure.

6. The semiconductor device of claim 4, further comprising:
a second dielectric structure disposed between the second nitride-based semiconductor multiple layered structure and the first conductive layer, wherein the first conductive layer extends from the substrate to a top surface of the second dielectric structure.

7. The semiconductor device of claim 6, wherein the second conductive layer is disposed in the second dielectric structure.

8. The semiconductor device of claim 6, wherein the first conductive layer extends along first oblique sidewalls of the second dielectric structure and the second nitride-based semiconductor multiple layered structure.

9. The semiconductor device of claim 8, wherein the first conductive layer extends along second oblique sidewalls of the second dielectric structure and the second nitride-based semiconductor multiple layered structure, wherein the second oblique sidewalls are opposite the first oblique sidewalls.

10. The semiconductor device of claim 1, wherein the first conductive layer further comprises a second portion in contact with the substrate, wherein the second nitride-based semiconductor multiple layered structure is located between the first and second portions of the first conductive layer.

11. The semiconductor device of claim 1, further comprising:
a nitride-based transistor disposed over the first nitride-based semiconductor multiple layered structure and located within the device region.

12. The semiconductor device of claim 1, further comprising:
a first contact via disposed between the second nitride-based semiconductor multiple layered structure and the first conductive layer, wherein the second conductive layer is electrically coupled to the first conductive layer through the first contact via;
a third conductive layer disposed between the second nitride-based semiconductor multiple layered structure and the second conductive layer; and
a second contact via disposed between the second conductive layer and the third conductive layer.

13. The semiconductor device of claim 1, wherein the first conductive layer entirely fills into the region between the first and second nitride-based semiconductor multiple layered structures.

14. The semiconductor device of claim 1, wherein the first portion of the first conductive layer is a through-GaN via (TGV) structure.

15. The semiconductor device of claim 1, wherein the first conductive layer extends across the second nitride-based semiconductor multiple layered structure.

16. A method for manufacturing a semiconductor device, comprising:
forming a nitride-based semiconductor multiple layered structure over a substrate;
forming a nitride-based transistor and a conductive structure over the nitride-based semiconductor multiple layered structure, wherein the nitride-based transistor is located within a device region of the substrate and the conductive structure is located within a peripheral region of the substrate;
removing a first portion of the nitride-based semiconductor multiple layered structure to expose a first portion of the substrate; and
forming a conductive layer extending from the device region to the peripheral region so as to cover the first portion of the substrate and the conductive structure.

17. The method of claim 16, wherein forming the conductive layer is performed such that a through-GaN via (TGV) structure in contact with the first portion of the substrate is formed.

18. The method of claim 17, wherein the semiconductor device is formed on a wafer, and the method further comprises:
performing a dicing process on the wafer along cut lines to singulate the semiconductor device, such that the TGV structure is farther away from one of the cut lines than the conductive structure.

19. The method of claim 16, further comprising:
removing a second portion of the nitride-based semiconductor multiple layered structure to expose a second portion of the substrate, wherein the conductive structure is located between the first portion and second portion of the substrate.

20. The method of claim 19, wherein the conductive layer is formed to extend across the conductive structure to cover the second portion of the substrate.

21-25. (canceled)
